(19) United States
(12) Patent Application Publication
(10) Pub. No.: US 2026/0329348 A1
(43) Pub. Date: Oct. 22, 2026

(54) Component Port Minimizing Liquid Blockage for an Electronic Device

(71) Applicant: Google LLC, Mountain View, CA (US)

(72) Inventors: Dennis Jacob McCray, San Diego, CA (US); Renato Cabanban, San Diego, CA (US); Kimberly Pratten, San Diego, CA (US)

(21) Appl. No.: 19/491,114

(22) PCT Filed: Jun. 8, 2023
(86) PCT No.: PCT/US2023/024804

§ 371 Date: Dec. 8, 2025

(51) Int. Cl. G06F 1/16; G01D 11/26; G04G 17/08; H04R 1/08; H05K 5/06

(52) U.S. Cl. CPC G06F 1/1656; G01D 11/26; G04G 17/08; G06F 1/163; H04R 1/086; H05K 5/069

(57) ABSTRACT

The present disclosure provides an electronic device. The electronic device includes a housing including an exterior wall. The electronic device also includes a port defining a pathway through the exterior wall for operational access by the component. The port includes a first section, the first section defining a first wall and an opening into the electronic device. The port also includes a second section, the second section defining a second wall and having an opening connected with the first section, the second section including one or more threads disposed thereon.

### FIELD

The present disclosure relates generally to an electronic device, and more particularly, to an electronic device having a port with sections capable of minimizing liquid blockage of the port.

### BACKGROUND

Electronic devices are devices that may be used for audio, video, or text communication, and further may provide a variety of other functionality to a user through the use of computing, programming, algorithms, or graphical interfaces. Electronic devices are also capable of determining information relating to a person using the device and/or the environment surrounding the device. In addition, the electronic device is able to output a signal to the user based on either the input of the user, the configuration of the electronic device, and/or the environment surrounding the electronic device.

One particular type of electronic device is a wearable device. Wearable devices are smart electronic devices that may be worn by a user a provide a variety of functionality to a user that a traditional watch or jewelry may not be able to provide. Wearable devices often have various components that provide functionality.

Some of the types of components require access to an external environment to enable their specific functionality to work properly. To provide this access, a port may be provided that creates a pathway from the component to the external environment. However, when the wearable device is exposed to an external environment, foreign objects may enter the port and remain trapped within the wearable device. For example, water or another liquid may enter the port and fail to evacuate or evaporate from the port in a timely manner. Until the foreign object is removed from the port, the foreign object may fully block or partially cover a pathway of the port. As a consequence, the performance of the components or the wearable device may be degraded.

Thus, a need exists for an electronic device capable of addressing these issues. For example, it would be desirable to have an electronic device having one or more ports capable of minimizing blockage by foreign objects such as liquids. It would also be beneficial for such an electronic device to be easily and efficiently manufactured.

### SUMMARY

Aspects and advantages of embodiments of the present disclosure will be set forth in part in the following description, or can be learned from the description, or can be learned through practice of the embodiments.

One example embodiment of the present disclosure is directed to an electronic device. The electronic device may include a housing including an exterior wall. The electronic device may also include a component carried within the housing. The electronic device may also include a port defining a pathway through the exterior wall for operational access by the component. The port may include a first section, the first section defining a first wall and an opening into the electronic device. The port may also include a second section, the second section defining a second wall and having an opening connected with the first section, the second section including one or more threads disposed thereon.

Another aspect of the present disclosure is directed to the component including a microphone, an altimeter, or a combination thereof.

Still another aspect of the present disclosure is directed to the one or more threads of the second section including a pitch, the pitch ranging from about 0.075 millimeters (mm) to about 0.4 mm.

In a further aspect, the present disclosure is directed to the port further including a third section defining a third wall having one or more threads disposed thereon.

In yet a further aspect, the present disclosure is directed to the first section and the second section extending in a first direction and the third section extending in a second direction.

In still a further aspect, the present disclosure is directed to the first direction and the second direction together defining an angle, the angle ranging from about 10 degrees to about 110 degrees.

In another aspect, the present disclosure is directed to the one or more threads of the third section including a pitch, the pitch ranging from about 0.1 millimeters (mm) to about 0.5 mm.

In yet another aspect, the present disclosure is directed to the third section being located adjacent to the second section.

In still another aspect, the present disclosure is directed to the first section including a counterbore, the counterbore having a diameter larger than a diameter of the second section.

In another further aspect, the present disclosure is directed to the component being capable of directly communicating with an external environment through an aperture of the component and the port.

In yet another further aspect, the present disclosure is directed to the second section including a coating, the coating including a hydrophobic coating.

In another embodiment, the present disclosure is directed to a method for manufacturing an electronic device capable of minimizing liquid blockage. In particular, the method may include providing an electronic device comprising a housing. The method may also include forming a port defining a pathway through the housing for access by a component. The forming of the port may include forming a first section into the housing, the first section defining a first wall and an opening into the electronic device. The forming of the port may also include forming a second section into the housing, the second section defining a second wall having one or more threads disposed thereon, the first section and the second section extending together in a first direction.

Another aspect of the present disclosure is directed to the pathway being formed via drilling into the housing.

Yet another aspect of the present disclosure is directed to the step of forming the port further including forming a third section into the housing, the third section defining a third wall having one or more threads disposed thereon.

Yet another aspect of the present disclosure is directed to the step of forming the port into the housing for the component including forming the first section and the second section via drilling into the housing in a first direction, and forming the third section via drilling into the housing in a second direction.

In yet another embodiment, the present disclosure is directed to another electronic device. The electronic device may include a component including an aperture. The electronic device may also include a port defining a pathway. The port may include a first section defining a first wall and an opening into the electronic device. The port may also include a second section defining a second wall having one or more threads disposed thereon. Further, the first section and the second section may extend in a first direction. The port may also include a third section defining a third wall having one or more threads disposed thereon. Further, the third section may extend in a second direction.

These and other features, aspects, and advantages of various embodiments of the present disclosure will become better understood with reference to the following description and appended claims. The accompanying drawings, which are incorporated in and constitute a part of this specification, illustrate example embodiments of the present disclosure and, together with the description, serve to explain the related principles.

### BRIEF DESCRIPTION OF THE DRAWINGS

Detailed discussion of embodiments directed to one of ordinary skill in the art is set forth in the specification, which makes reference to the appended figures, in which:

FIG. 1 provides a front, perspective view of an embodiment of an electronic device according to the present disclosure;

FIG. 2 provides a rear, perspective view of the electronic device of FIG. 1;

FIG. 3 provides a side, perspective view of the electronic device of FIGS. 1-2;

FIG. 4 provides a partial perspective view of the electronic device of FIGS. 1-3, particularly illustrating a port located on a side of the electronic device;

FIG. 5 provides a side, cross-sectional view of the electronic device of FIGS. 1-3, particularly illustrating the structure of the port located on a side of the electronic device;

FIG. 6 provides a perspective view of the cross-section of the electronic device of FIG. 5, particularly illustrating the structure of the port located on a side of the electronic device;

FIG. 7A provides a side, cross-sectional view of the electronic device of FIGS. 1-3, taken at cut line 7A-7A shown in FIG. 5, particularly illustrating the structure of the second section of the port located on a side of the electronic device;

FIG. 7B provides a side, cross-sectional view of the electronic device of FIGS. 1-3, taken at cut line 7B-7B shown in FIG. 6, particularly illustrating the structure of the third section of the port located on a side of the electronic device;

FIG. 8 provides a flow diagram of an embodiment of a method of manufacturing an electronic device capable of minimizing liquid blockage according to the present disclosure;

FIGS. 9-12 provide illustrations of graphs of a frequency response measurement at selected time intervals for a conventional electronic device and the electronic device according to the present disclosure.

Reference numerals that are repeated across plural figures are intended to identify the same features in various implementations.

### DETAILED DESCRIPTION

Any of the features, components, or details of any of the arrangements or embodiments disclosed in this application, including without limitation any of the electronic device embodiments and any of the methods of manufacturing said electronic device disclosed below, are interchangeably combinable with any other features, components, or details of any of the arrangements or embodiments disclosed herein to form new arrangements and embodiments.

An electronic device, such as a laptop, a desk-top computer, or wearable devices (e.g., wristwatch, smartwatch, smart jewelry, fitness tracker, head mounted display) may include various types of internal components to provide the functionalities thereof. However, some of these components may require access to an external environment to provide their particular functionality. To this end, a port may be included in various types of electronic devices to provide a pathway to the external environment. For example, the port may allow for the output of audio and the influx of air resulting from atmospheric pressure which may be used for readings from an internal component, such as an altimeter. However, the port may be susceptible to clogging by a foreign debris such as a fluid or water. Until the blockage of the port by the foreign debris is removed, the output of audio or the influx of air used for the internal components may be hindered. Thus, the overall functionality of the component may be reduced.

Thus, the present disclosure is related to an electronic device having a component port design that addresses the aforementioned issues. In particular, the electronic device of the present disclosure includes a component having an aperture and a port defining a pathway. The port includes a first section defining a first wall and an opening into the electronic device. The port also includes a second section defining a second wall having one or more threads disposed thereon. Thus, by providing a wall with threads on the port, the liquid may rest upon the threads of the wall, while the threads provide gaps through which air can travel, such that the pathway of the port is not blocked. Further, air may be able to pass around the liquid in the pathway such as via the threads such that the liquid is more easily evaporated and/or evacuated from the port.

As such, without intending to be limiting, certain benefits provided by the present disclosure include a port structure capable of minimizing the impact that foreign objects such as liquids or water may have on the functionality of the components contained within an electronic device. Further, by encompassing these features in a singular port, ease and efficiency of manufacturing may be increased.

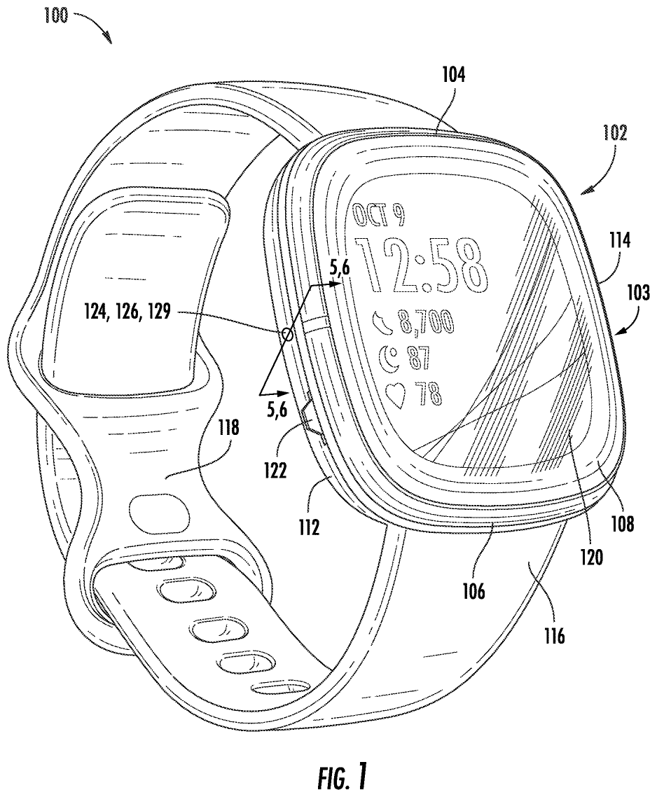

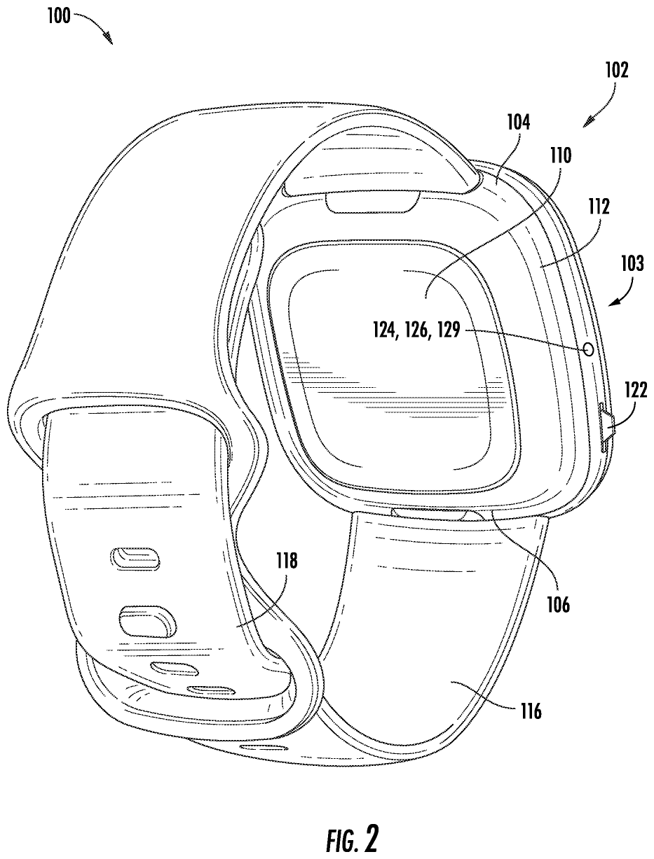

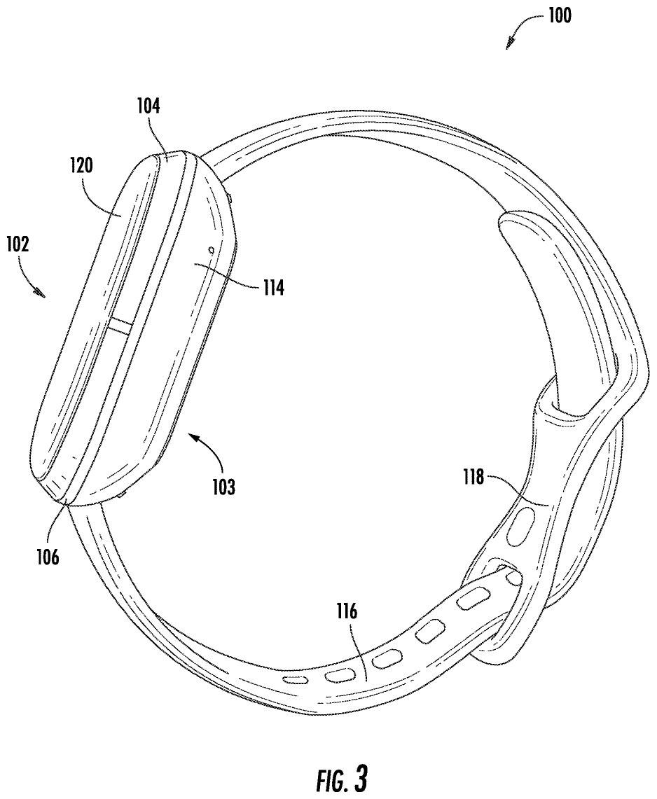

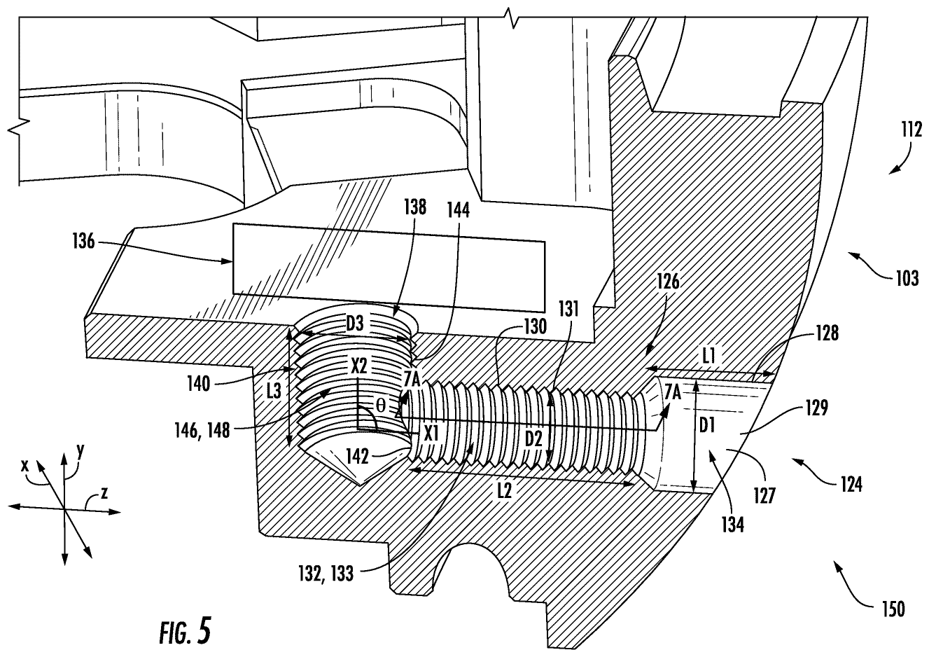

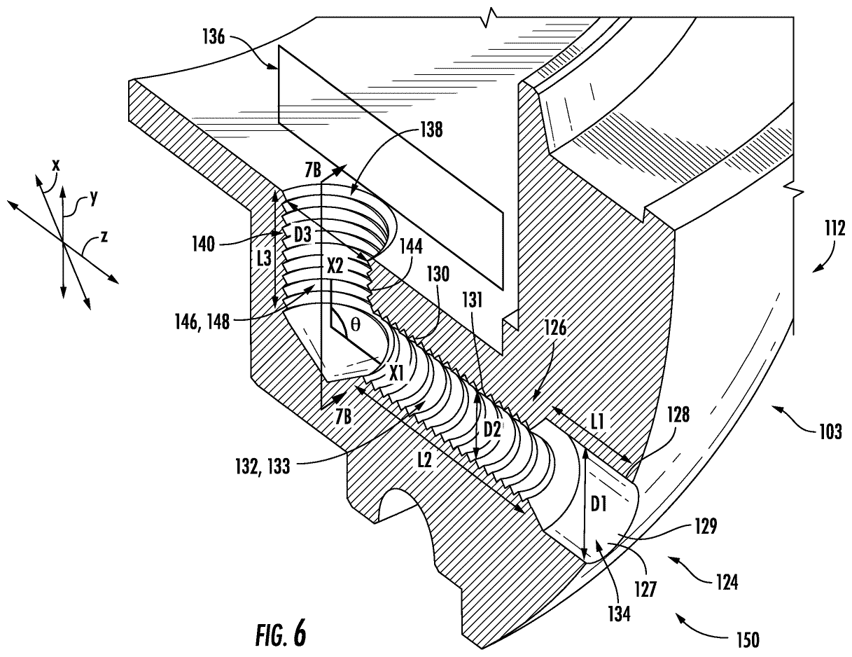

FIGS. 1-3 show an electronic device according to one embodiment of the present disclosure. Further, FIG. 1 includes cut line 5-5 and cut line 6-6, which correspond to the cross-sections depicted in FIG. 5 and FIG. 6, respectively. Such cross-sections provide a detailed view of the port 124 as will be discussed in greater detail hereinbelow.

Referring now to FIGS. 1-3, the electronic device 100 includes a housing 102 having a top 104, bottom 106, a front 108, a back 110, a first side 112, and a second side 114. The housing 102 may also define or include an exterior wall 103 of the electronic device 100. The electronic device 100 can also include an attachment implement 116, a securement implement 118, a display 120, a button 122 located on the housing 102, and a port 124. The port 124 may be positioned on the housing 102 and provide the aforementioned benefits of the present invention as will be described in greater detail hereinbelow.

Without intending to limit the present disclosure to a particular configuration, the top 104 and the bottom 106 of the housing 102 may be connected to the attachment implement 116. The attachment implement 116 may be capable of attaching the electronic device 100 to a user of said electronic device 100. The attachment implement 116 may take the form of, but should not be construed as limited to, a wristband, a strap, a rope, an elastic band, or any other form of attachment one of ordinary skill in the art would use to attach an electronic device 100 to a user of said electronic device 100.

The securement implement 118 may be located on the attachment implement 116. Further, the securement implement 118 may be positioned or located opposite of the housing 102 on an opposing end of the attachment implement 116. The securement implement 118 may be capable of improving the attachment of the attachment implement 116 upon the user. The securement implement 118 may include, but should not be construed as limited to, a latch, a pin and hole locking mechanism, a magnet system, a lock, a clip, or any other type of securement that one of ordinary skill would consider. It should be noted that a securement implement 118 may not be necessary for an electronic device 100 to be secured to a user. For example, an electronic device 100 may be secured to a user with a strap which is then tied around the user's wrist or other suitable appendage.

The display 120 may be capable of providing the wearer with a variety of information such as the time, the date, body signals, readings based upon user input, etc. Body signals may include, but are not limited to, heart rate, heart pressure, temperature, oxygen levels, or any other body signal that one of ordinary skill in the art would understand that can be measured by an electronic device 100. Readings based upon user input may include, but are not limited to, the number of steps a user has taken, the distance traveled by the user, the sleep schedule of the user, travel routes of the user, elevation climbed by the user, or any other metric that one of ordinary skill in the art would understand that can be gathered into an electronic device 100. Further, either body signals or readings based upon user input may be used to calculate further analytics to provide to the user such as a fitness score, a sleep quality score, the number of calories a user has burned. Moreover, the electronic device 100 may also be capable of taking in outside input irrespective of the user such as ambient teacher in the environment, the amount of sun exposure the watch is subjected to, the atmospheric pressure of the environment, air quality of the environment, the location of the electronic device 100 based on a global positioning system (GPS), or other outside factors that one of ordinary skill in the art would understand an electronic device 100 would be capable of measuring.

The button 122 is shown as being positioned on the first side 112 of the housing. However, the button 122 may also be positioned on the second side 114, the top 104, the bottom 106, the front 108, or the back 110 of the housing 102. The button 122 may be provided on the electronic device 100 to allow for the user to interact with the electronic device 100 and for the user to provide a form of input into the electronic device 100. For illustration purposes, one button 122 is shown on the electronic device 100 embodied in FIGS. 1-3. However, an electronic device 100 may have any number of buttons located on it to allow the user to further interact with the electronic device 100 to provide alternative inputs. It should also be noted that a button 122 may not be necessary for a user to interact with the electronic device 100. Instead, the electronic device 100 may utilize the display 120 to take inputs via the touch of the user or through voice commands of the user.

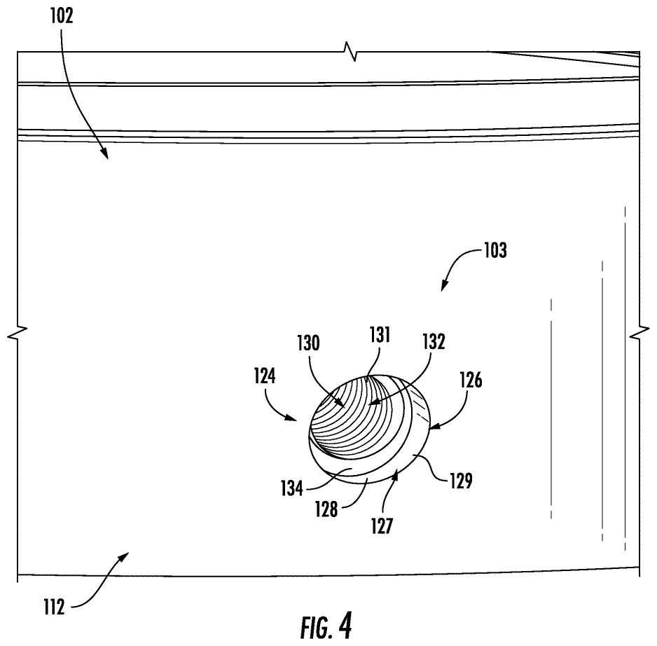

FIG. 4 illustrates a partial perspective view of the electronic device of FIGS. 1-3, particularly illustrating a port 124 located on a side 112 of the electronic device 100. As shown, the port 124 may be positioned or located on the first side 112 of the electronic device 100. However, the port 124 may also be positioned on the second side 114, the top 104, the bottom 106, the front 108, or the back 110 of the housing 102. Multiple ports 124 may also be provided, and the multiple ports 124 may be positioned on one face or multiple faces of the housing 102 such as the top 104, the bottom 106, the front 108, the back 110, the first side 112, or the second side 114.

Referring now to FIGS. 5-6, FIG. 5 illustrates a side, cross-sectional view of the electronic device of FIGS. 1-3 taken at cut line 5-5 shown in FIG. 1, and FIG. 6 illustrates a perspective view of the cross-section of FIG. 5 taken at cut line 6-6 shown in FIG. 1, particularly illustrating the structure of the port 124 positioned on the housing 102. As shown, the port 124 defines a pathway 126 from an external environment 150 (e.g., the air or atmosphere surrounding a user of the electronic device 100) to a component 136. Thus, the port 124 may allow for the intake or output of signals through the port 124. For example, if the component 136 is a microphone or an altimeter, the intake or output of signals may be output or received through an aperture 138 of the component 136 to or from the external environment 150 through the pathway 126 of the port 124. As described, the aperture 138 of the component 136 is provided for the intake or output of signals from the component 136.

As shown, the port 124 may include a first section 127, a second section 130, and a third section 140 that together form the pathway 126 of the port 124 from the component 136 to the external environment 150. The first section 127 may include a first wall 128 and define an opening 129 into the housing 102 of the electronic device 100. The first section 127 may be formed via drilling into the housing 102 of the electronic device 100. However, the first section 127 may be better understood with reference to the second section 130 and will be described in greater detail with reference to the second section 130 hereinbelow.

The second section 130 may include a second wall 131 having one or more threads 132 disposed thereon. Together, the first section 127 and the second section 130 may extend in a first direction X1. For example, the first section 127 and the second section 130 together may be coaxial or substantially coaxial with each other in the first direction X1. The second section 130 and the thread(s) 132 of the second section 130 may be formed via drilling into the housing 102 of the electronic device 100 using, for example, a drill with a threaded drill bit.

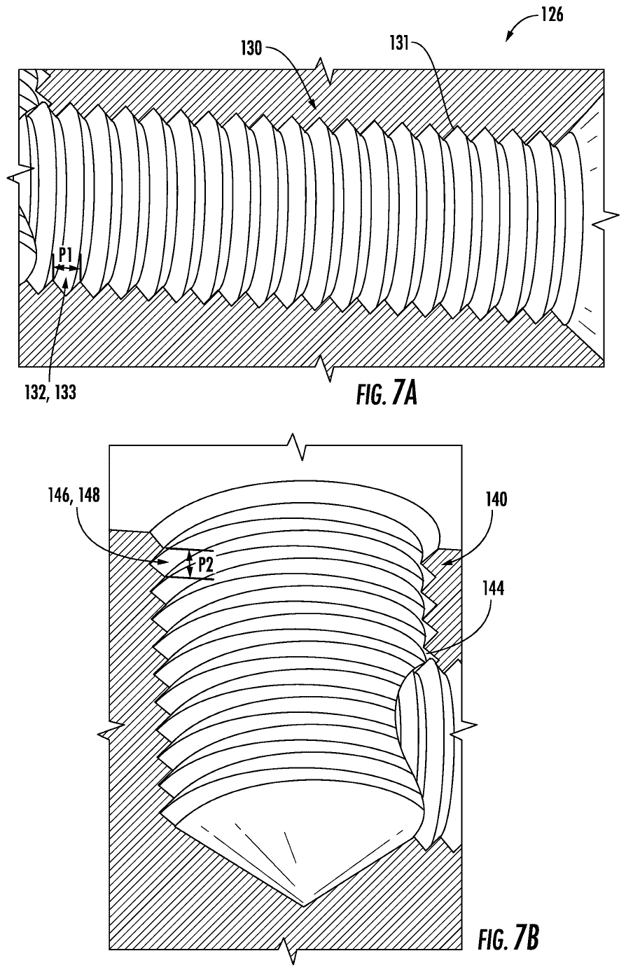

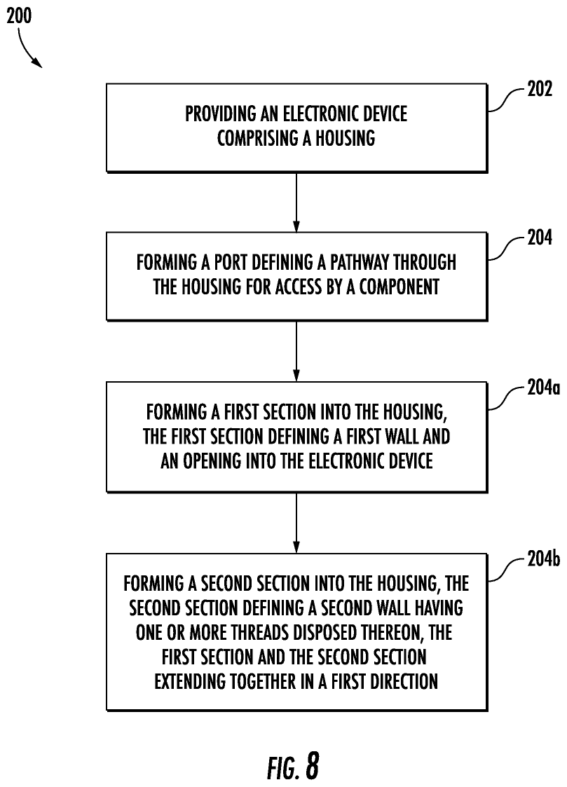

If multiple threads 132 are provided on the second section 130, the threads 132 together may define a pitch P1 as shown in FIG. 7A. For example, referring now to FIG. 7A, the pitch P1 of the threads 132 may range from about 0.03 millimeters (mm) to about 0.8 mm, such as about 0.05 mm to about 0.6 mm, such as about 0.075 mm to about 0.4 mm.

Referring back to FIGS. 5-6, the second section 130 may also include a length L2 and a diameter D2. For example, the length L2 may range from about 0.5 mm to about 2.75 mm, such as about 0.75 mm to about 2.5 mm, such as about 1 mm to about 2.25 mm. Further, the diameter D2 may range from about 0.4 mm to about 1.6 mm, such as about 0.6 mm to about 1.4 mm, such as about 0.8 mm to about 1.2 mm. By providing a second section 130 with the length L1 and the diameter D2, benefits may be provided that will be further detailed below.

Returning to the first section 127, the first section 127 may include a counterbore 134. The counterbore 134 may be provided such that the surface of the first section 127 is smooth substantially smooth. In addition, the counterbore 134 may define a diameter D1 and a length L1. For example, the diameter D1 of the counterbore 134 may be larger than the diameter D2 of the second section 130. Specifically, the diameter D1 may range from about 110% to about 200% of the diameter D2, such as 125% to about 175% of the diameter D2, such as about 135% to about 160% of the diameter D2. By providing a counterbore 134 with a diameter D2 larger than the diameter D1 of the first section 127, the overall aesthetic of the may be improved. For example, the counterbore 134 may hide or substantially hide the thread(s) 132 of the first section 127 from a user of the electronic device 100. In addition, these benefits may also be realized through providing a counterbore 134 with a length L1. Specifically, the length L1 may be at least about 0.5 mm, such as at least about 0.6 mm, such as at least about 0.75 mm. Thus, like the diameter D1, the length L1 may also assist in hiding the thread(s) 132 from the view of a user of the electronic device 100.

Turning now to the third section 140, the third section 140 may be adjacent to the second section 130 and define a connection 142 with the second section 130. In addition, the third section 140 may include a third wall 144 having one or more threads 146 disposed thereon. The third section 140 and the thread(s) 146 of the third section 140 may also be formed via drilling similar to the second section 130. If multiple threads 146 are provided, the threads together may define a pitch P2 as shown in FIG. 7B. For example, referring now to FIG. 7B, the pitch P2 of the threads 146 may range from about 0.05 millimeters (mm) to about 1 mm, such as about 0.075 mm to about 0.75 mm, such as about 0.1 mm to about 0.5 mm.

Referring back to FIGS. 5-6, the third section 140 may also include a length L3 and a diameter D3. For example, the length L3 may range from about 0.6 mm to about 2.0 mm, such as about 0.8 mm to about 1.6 mm, such as about 1 mm to about 1.4 mm. Further, the diameter D3 may range from about 0.6 mm to about 2.0 mm, such as about 0.8 mm to about 1.6 mm, such as about 1 mm to about 1.4 mm. By providing a third section 140 with the length L3 and the diameter D3, benefits may be provided that will be further detailed below.

The third section 140 may extend in a second direction X2 that is different from the first direction X2 of the first and section sections 127, 130. For example, the first direction X1 and the second direction X2 may together define an angle θ. The angle θ may range from about 5 degrees to about 145 degrees, such as about 7 degrees to about 130 degrees, such as about 10 degrees to about 110 degrees. The angle θ may also be further defined such that the first direction X1 is orthogonal with the second direction X2. Benefits of providing a third section 140 as described above will be discussed in greater detail below.

The thread(s) 132, 146 described herein provide a distinct advantage when utilized according to the present disclosure. Specifically, the thread(s) 132, 146 applied on the second wall 131 of the second section 130 or the third wall 144 of the third section 140 may help minimize the negative impact liquid has on the component 136 when liquid enters the port 124. For example, if a liquid such as water enters a conventional port, the liquid may clog or substantially block up a conventional port. However, by providing the thread(s) 132, 146 on the port 124 as present described, the liquid or water may sit or rest within the thread(s) 132, 146 such that the port 124 is not clogged or substantially blocked by the liquid. In an exemplary embodiment, this advantage is evident when the component 136 requires a free and unblocked pathway from the component 136 to the external environment 150 such that the component 136 is capable of directly communicating with an external environment 150 through the aperture 138 of the component 136 and the port 124. For example, if the component 136 is a sensor such as an altimeter, the sensor may misread the conditions of the external environment 150 due to a blockage of the port 124 by a liquid such as water. However, by defining the thread(s) 132, 146 on the port 124, the liquid may no longer block or clog the port 124. Thus, the sensor is less likely to provide a misreading of the conditions of the external environment 150 because the thread(s) 132, 146 are provided. In another example, if the component 136 is a device that outputs signals, like a microphone or speaker, the quality of the audio output by the microphone may be reduced if a conventional port is clogged or substantially blocked by a liquid or water. However, by defining the thread(s) 132, 146 on the port 124, the liquid may instead rest within the thread(s) 132, 146 and the audio output of the microphone may be unhindered by the liquid.

To provide further benefits, the thread(s) 132 of the second section 130 may have the length L2 and the diameter D2, and the thread(s) 146 of the third section 140 may have the length L3 and the diameter D3 as described above. Specifically, the lengths L2, L3 and the diameters D2, D3 may provide a volume in which there is more space for the thread(s) 132, 146 to capture liquids such as water. In particular, more volume can be made available within the thread(s) 132, 146 when longer lengths L2, L3 or diameters D2, D3 are provided. Thus, by selecting the length L2, L3, or the diameters D2, D3 more liquid can be captured within the thread(s) 132, 146 without clogging or substantially blocking the port 124. As a result, the input and output of signals through the port 124 may be less susceptible to being negatively impacted by liquids such as water. This benefit is especially present when the thread(s) 132, 146 span the entire lengths L2, L3 or the entire diameters D2, D3 of the second section 130 and the third section 140.

To provide further benefits, the first and second sections 127, 130 may extend in a first direction X1 and the third section 140 may extend in a second direction X2 as described above. In particular, by having the third section 140 extend in a second direction X2 that is different from the first direction X1, the thread(s) 146 may be capable of capturing fluids at an angle that is different from the first direction X1. As a result of this, the third section 140 may be able to prevent fluids such as water from negatively impacting the input and output of signals through the port 124 when the electronic device 100 is oriented in a different direction or manner when compared to the second section 130. Conversely, the thread(s) 132 of the second section 130 may be capable of capturing fluids at an angle that is different from the second direction X2. Thus, by providing an angle θ between the two directions X1, X2, fluids may further be prevented from negatively impacting the function of the port 124.

To provide further benefits, the thread(s) 132 of the second section 130 may include a coating 133 or the thread(s) 146 of the third section 140 may include a coating 148. For example, the coating 133, 148 may be at least a hydrophobic coating such as acrylics, epoxies, polyethylene, polystyrene, polyvinylchloride, polytetrafluorethylene, polydimethylsiloxane, polyesters, polyurethanes, or combinations thereof. The coating 133, 148 may also be an anodization on the thread(s) 132, 146. By providing a coating 133, 148, water may evaporate or evacuate from the port 124 more readily. Further, a coating 133, 148 may also help prevent degradation in the quality of the input or output of signals as described above. Specifically, the coatings 133, 148 may result in a liquid such as water resting atop the thread(s) 132, 146, instead of filling the thread(s) 132, 146. Because the liquid does not fill the thread(s) 132, 146, air and signals may be able to flow through the port 124. In particular, if liquid is located within the port 124, air may be able to flow alongside, under, or over the liquid within the port 124. Further, because air can flow through the port 124 around the liquid, the air may allow for the liquid to more readily evaporate or evacuate from the port 124. Thus, the coating(s) 133, 148 may provide multiple advantages when used with the thread(s) 132, 146.

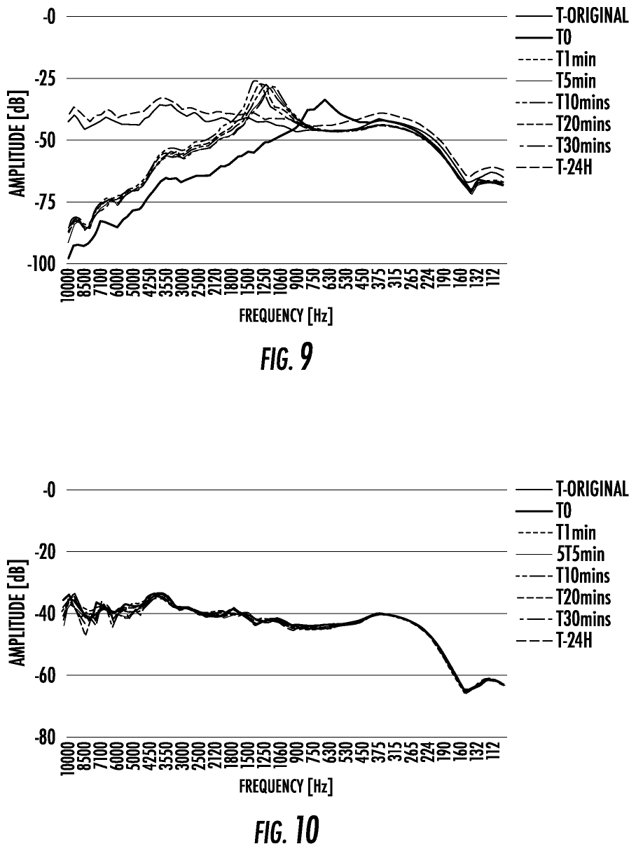

FIG. 8 shows a flowchart that illustrates a method 200 of manufacturing an electronic device capable of minimizing liquid blockage according to the present disclosure. The method 200 includes step 202, which involves providing an electronic device comprising a housing. The method 200 also include step 204, which involves forming a port defining a pathway through the housing for access by a component. The step 204 may also include sub-steps. For example, the step 204 may include step 204a, which involves forming a first section into the housing, the first section defining a first wall and an opening into the electronic device. The step 204 may also include step 204b, which involves forming a second section into the housing, the second section defining a second wall having one or more threads disposed thereon, the first section and the second section extending together in a first direction. The method 200 may also include additional steps. For example, the method 200 may include coating the second section with a coating such as a hydrophobic coating.

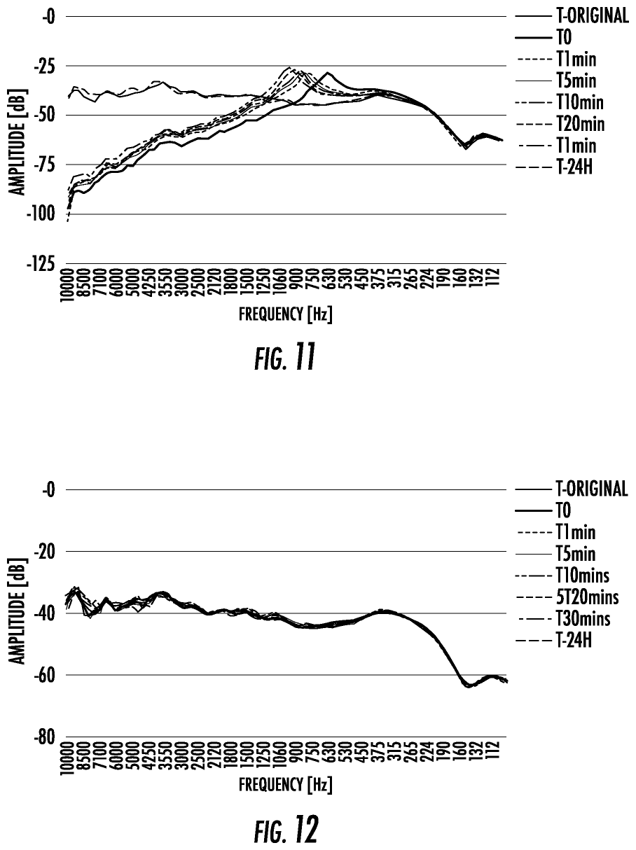

The present disclosure may be further understood with reference to the following example(s). For example, referring now to FIGS. 9-12, illustrations of graphs of a frequency response measurement at selected time intervals for a conventional electronic device (e.g., no threads) and the electronic device according to the present disclosure are provided. As shown in FIGS. 9-12, an experiment was conducted to determine how different port geometries and configurations affect the overall performance of an electronic device when the electronic device is submerged in water. Specifically, an electronic device having a conventional port geometry and an electronic device having a threaded port were submerged in water for a period of time, removed from the water, then vibrated to simulate a potential use of the electronic device if a user of such a device was submerged in water and then left the water and walked with the electronic device. In addition, each of the devices underwent simulations under the presumption that the electronic device was worn on the right or left wrist of a user of the electronic device by either having the electronic device face down or face upward when submerged and vibrated.

After the simulation of water submersion was conducted, various periods of time were allotted before the functionality of the electronic devices were tested. After the dwelling period, each of the electronic devices were tested for their frequency response measurement response. In particular, time T-ORIGINAL is the frequency response via the port when the port is dry. Particularly, for T-ORIGINAL, the electronic devices were tested without submerging the electronic devices in water for use as a control. Time T0 is the frequency response upon immersion were the device was allowed to dwell (dry) for 0 seconds after simulation (immersion in water). Time T1min is the frequency response via the port for the device after it was allowed to dwell (dry) for 1 minute after the simulation (immersion). Time T5mins is the frequency response via the port for the device after it was allowed to dwell (dry) for 5 minutes after the simulation. Time T10mins is the frequency response via the port for the device after it was allowed to dwell (dry) for 10 minutes after the simulation. Time T20mins is the frequency response via the port for the device after it was allowed to dwell (dry) for 20 minutes after the simulation. Time T30mins is the frequency response via the port for the device after it was allowed to dwell (dry) for 30 minutes after the simulation. Time T24H is the frequency response via the port for the device after it was allowed to dwell (dry) for 24 hours after the simulation.

The results of the test are shown by FIGS. 9-12. In particular, FIGS. 9 and 11 correspond to an electronic device having a conventional port geometry, while FIGS. 10 and 12 correspond to the electronic device 100 having the threaded port 124. Further, FIGS. 9-10 correspond to the electronic device being worn on the right wrist of a user, while FIGS. 11-12 correspond to the electronic device being worn on the left wrist of a user.

As shown by FIGS. 9-12, the electronic device having a threaded port geometry provided overall better functionality for each of the dwelling times. Specifically, when comparing FIGS. 10 and 12 to FIGS. 9 and 11, it can be seen that the threaded port 124 reduced or negated the amount of time necessary for the port to be able to observe a variety of different frequencies of sounds without reducing the amplitude or overall intensity, or power level of the sound observed. In addition, this benefit over an electronic device having a conventional port geometry was observed regardless of whether the electronic device was worn on the right wrist or the left wrist of a user. Thus, as can be seen by the graphs of FIGS. 9-12, the electronic device 100 having thread(s) 132 and thread(s) 146 may provide the distinct advantage of reducing the effect liquids such as water have on the overall functionality of the component 136 of the electronic device 100 when compared to electronic devices that do not have threads.

While various embodiments of the present disclosure have been described above, it should be understood that they have been presented by way of example only, and not by way of limitation. Likewise, the various diagrams may depict an example architectural or other configuration for the disclosure, which is done to aid in understanding the features and functionality that can be included in the disclosure. The disclosure is not restricted to the illustrated example architectures or configurations but can be implemented using a variety of alternative architectures and configurations. Additionally, although the disclosure is described above in terms of various exemplary embodiments and implementations, it should be understood that the various features and functionality described in one or more of the individual embodiments are not limited in their applicability to the particular embodiment with which they are described. They instead can be applied, alone or in some combination, to one or more of the other embodiments of the disclosure, whether or not such embodiments are described, and whether or not such features are presented as being a part of a described embodiment. Thus, the breadth and scope of the present disclosure should not be limited by any of the above-described exemplary embodiments.

Unless otherwise defined, all terms (including technical and scientific terms) are to be given their ordinary and customary meaning to a person of ordinary skill in the art, and are not to be limited to a special or customized meaning unless expressly so defined herein. It should be noted that the use of particular terminology when describing certain features or aspects of the disclosure should not be taken to imply that the terminology is being re-defined herein to be restricted to include any specific characteristics of the features or aspects of the disclosure with which that terminology is associated. Terms and phrases used in this application, and variations thereof, especially in the appended claims, unless otherwise expressly stated, should be construed as open ended as opposed to limiting. As examples of the foregoing, the term ‘including’ should be read to mean ‘including, without limitation,’ ‘including but not limited to,’ or the like; the term ‘comprising’ as used herein is synonymous with ‘including,’ ‘containing,’ or ‘characterized by,’ and is inclusive or open-ended and does not exclude additional, unrecited elements or method steps; the term ‘having’ should be interpreted as ‘having at least;’ the term ‘includes’ should be interpreted as ‘includes but is not limited to;’ the term ‘example’ is used to provide exemplary instances of the item in discussion, not an exhaustive or limiting list thereof; adjectives such as ‘known’, ‘normal’, ‘standard’, and terms of similar meaning should not be construed as limiting the item described to a given time period or to an item available as of a given time, but instead should be read to encompass known, normal, or standard technologies that may be available or known now or at any time in the future; and use of terms like ‘preferably,’ ‘preferred,’ ‘desired,’ or ‘desirable,’ and words of similar meaning should not be understood as implying that certain features are critical, essential, or even important to the structure or function of the present disclosure, but instead as merely intended to highlight alternative or additional features that may or may not be utilized in a particular embodiment of the present disclosure. Likewise, a group of items linked with the conjunction ‘and’ should not be read as requiring that each and every one of those items be present in the grouping, but rather should be read as ‘and/or’ unless expressly stated otherwise. Similarly, a group of items linked with the conjunction ‘or’ should not be read as requiring mutual exclusivity among that group, but rather should be read as ‘and/or’ unless expressly stated otherwise.

Where a range of values is provided, it is understood that the upper and lower limit, and each intervening value between the upper and lower limit of the range is encompassed within the embodiments.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity. The indefinite article “a” or “an” does not exclude a plurality. A single processor or other unit may fulfill the functions of several items recited in the claims. The mere fact that certain measures are recited in mutually different dependent claims does not indicate that a combination of these measures cannot be used to advantage. Any reference signs in the claims should not be construed as limiting the scope.

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

All numbers expressing quantities of ingredients, reaction conditions, and so forth used in the specification are to be understood as being modified in all instances by the term ‘about.’ Accordingly, unless indicated to the contrary, the numerical parameters set forth herein are approximations that may vary depending upon the desired properties sought to be obtained. At the very least, and not as an attempt to limit the application of the doctrine of equivalents to the scope of any claims in any application claiming priority to the present application, each numerical parameter should be construed in light of the number of significant digits and ordinary rounding approaches.

All of the features disclosed in this specification (including any accompanying exhibits, claims, abstract and drawings), and/or all of the steps of any method or process so disclosed, may be combined in any combination, except combinations where at least some of such features and/or steps are mutually exclusive. The disclosure is not restricted to the details of any foregoing embodiments. The disclosure extends to any novel one, or any novel combination, of the features disclosed in this specification (including any accompanying claims, abstract and drawings), or to any novel one, or any novel combination, of the steps of any method or process so disclosed.

While the present subject matter has been described in detail with respect to various specific example embodiments thereof, each example is provided by way of explanation, not limitation of the disclosure. Those skilled in the art, upon attaining an understanding of the foregoing, can readily produce alterations to, variations of, and equivalents to such embodiments. Accordingly, the subject disclosure does not preclude inclusion of such modifications, variations and/or additions to the present subject matter as would be readily apparent to one of ordinary skill in the art. For instance, features illustrated or described as part of one embodiment can be used with another embodiment to yield a still further embodiment. Thus, it is intended that the present disclosure cover such alterations, variations, and equivalents.

What is claimed is:

1. An electronic device, the electronic device comprising:
a housing including an exterior wall;
a component carried within the housing;
a port defining a pathway through the exterior wall for operational access by the component, the port comprising:
a first section, the first section defining a first wall and an opening into the electronic device;
a second section, the second section defining a second wall and having an opening connected with the first section, the second section including one or more threads disposed thereon.

2. The electronic device of claim 1, the component comprising a microphone, an altimeter, or a combination thereof.

3. The electronic device of claim 1, the one or more threads of the second section comprising a pitch, the pitch ranging from about 0.075 millimeters (mm) to about 0.4 mm.

4. The electronic device of claim 1, the port further comprising:
a third section defining a third wall having one or more threads disposed thereon.

5. The electronic device of claim 4, the first section and the second section extending in a first direction and the third section extending in a second direction.

6. The electronic device of claim 5, the first direction and the second direction together defining an angle, the angle ranging from about 10 degrees to about 110 degrees.

7. The electronic device of claim 4, the one or more threads of the third section comprising a pitch, the pitch ranging from about 0.1 millimeters (mm) to about 0.5 mm.

8. The electronic device of claim 4, the third section located adjacent to the second section.

9. The electronic device of claim 1, the first section comprising a counterbore, the counterbore having a diameter larger than a diameter of the second section.

10. The electronic device of claim 1, the component being capable of directly communicating with an external environment through an aperture of the component and the port.

11. The electronic device of claim 1, the second section comprising a coating, the coating comprising a hydrophobic coating.

12. A method of manufacturing an electronic device capable of minimizing liquid blockage, the method comprising:
providing the electronic device, the electronic device comprising a housing;
forming a port defining a pathway through the housing for access by a component, the forming of the port comprising:
forming a first section into the housing, the first section defining a first wall and an opening into the electronic device,
forming a second section into the housing, the second section defining a second wall having one or more threads disposed thereon, the first section and the second section extending together in a first direction.

13. The method of claim 12, the pathway being formed via drilling into the housing.

14. The method of claim 12, the forming of the port further comprising:
forming a third section into the housing, the third section defining a third wall having one or more threads disposed thereon.

15. The method of claim 14, the step of forming the port into the housing for the component comprising:
forming the first section and the second section via drilling into the housing in the first direction, and
forming the third section via drilling into the housing in a second direction.

16. The method of claim 15, the first direction and the second direction together defining an angle, the angle ranging from about 10 degrees to about 110 degrees.

17. The method of claim 12, the component comprising a microphone, an altimeter, or a combination thereof.

18. The method of claim 12, the first section comprising a counterbore.

19. The method of claim 12 further comprising:
coating the second section with a hydrophobic coating.

20. An electronic device, the electronic device comprising:
a component comprising an aperture;
a port defining a pathway, the port comprising:
a first section, the first section defining a first wall and an opening into the electronic device,
a second section, the second section defining a second wall having one or more threads disposed thereon, the first section and the second section extending in a first direction;
a third section defining a third wall having one or more threads disposed thereon, the third section extending in a second direction.
